(19) United States
(12) Patent Application Publication
(10) Pub. No.: US 2025/0236523 A1
(43) Pub. Date: Jul. 24, 2025

(54) MANUFACTURING METHOD OF LASER-INDUCED GRAPHENE AND LASER-INDUCED GRAPHENE MANUFACTURED THEREBY

(71) Applicant: PUSAN NATIONAL UNIVERSITY INDUSTRY-UNIVERSITY COOPERATION FOUNDATION, Busan (KR)

(72) Inventors: Seoung-Ki Lee, Busan (KR); Jung Woo Lee, Busan (KR); Se-Hun Kwon, Busan (KR)

(73) Assignee: PUSAN NATIONAL UNIVERSITY INDUSTRY-UNIVERSITY COOPERATION FOUNDATION, Busan (KR)

(21) Appl. No.: 19/035,912

(22) Filed: Jan. 24, 2025

(30) Foreign Application Priority Data
Jan. 24, 2024 (KR) 10-2024-0010594

(51) Int. Cl. C01B 32/184

(52) U.S. Cl. CPC C01B 32/184; C01B 2204/22; C01P 2002/82; C01P 2004/03

(57) ABSTRACT

A manufacturing method of high-resolution laser-induced graphene (LIG), includes: a) a step of depositing a metal on a wafer to manufacture a metal-deposited wafer; b) a step of spin-coating the metal-deposited wafer with a poly(amic acid) (PAA) solution; c) a step of patterning the spin-coated PAA by irradiating it with ultraviolet (UV) light; d) a step of imidizing the patterned PAA by applying heat thereto to manufacture polyimide (PI); and e) a step of irradiating the PI with a laser to manufacture laser-induced graphene.

### CROSS REFERENCE TO RELATED APPLICATION

This application claims priority to Korean Patent Application No. 10-2024-0010594 (filed on Jan. 24, 2024), which is hereby incorporated by reference in its entirety.

### BACKGROUND

The present invention relates to a manufacturing method of laser-induced graphene (LIG) and laser-induced graphene manufactured thereby, and more specifically, to a manufacturing method of laser-induced graphene, the manufacturing method including: a) a step of depositing a metal on a wafer to manufacture a metal-deposited wafer; b) a step of spin-coating the metal-deposited wafer with a poly(amic acid) (PAA) solution; c) a step of patterning the spin-coated PAA by irradiating it with ultraviolet (UV) light; d) a step of imidizing the patterned PAA by applying heat thereto to manufacture polyimide (PI); and e) a step of irradiating the PI with a laser to manufacture laser-induced graphene, and LIG manufactured thereby.

Recently, a laser-induced graphene (LIG) synthesis technology has been reported, which enables to easily synthesize porous carbon materials by laser-graphitizing various polymer precursors including polyimide (PI), polyether imide (PEI), wood, and paper under ambient conditions. LIG manufactured through a laser heat treatment system is manufactured on a flexible polymer substrate, and above all, it has excellent conductivity and a large surface area due to its porous structure, and therefore, it is being actively studied in electrochemical applications such as micro-supercapacitors, batteries, gas, and biosensors.

Despite these various applicability of LIG, in principle, it can only be synthesized on plastic substrates, and due to the limitation of pattern resolution, devices of only a primitive shape may be manufactured, and the LIG is not compatible with post-processing or packaging technology for practical products.

More specifically, the resolution of porous carbon structures synthesized using a general infrared CO₂ laser is limited to 50 to 100 μm due to beam optics and diffraction limitations, making it impossible to manufacture fine patterns. Accordingly, several studies have been conducted to improve the resolution using short-wavelength ultraviolet (UV) or visible-light lasers, but these methods could be applied only in a scanning electron microscope (SEM)-equipped system under vacuum.

In addition, the production of porous carbon materials is limited to polymer substrates rather than semiconductor substrates (substrates such as silicon, glass, and sapphire), and the polymer substrates are not compatible with the post-processing essential for the production of semiconductor devices. As a result, despite the potential of the material itself, its application to practical fields is limited.

### RELATED ART

KR Patent No. 10-1984694 B1

### SUMMARY

An object of the present invention is to provide a manufacturing method of laser-induced graphene (LIG) having a porous structure on a semiconductor substrate (SiO₂/Si wafer) rather than a polymer substrate, thereby achieving compatibility with the post-process of the semiconductor device manufacturing process and providing a manufacturing method of LIG having excellent resolution.

Another object of the present invention is to provide LIG manufactured by a method according to the manufacturing method of LIG.

The technical problems to be solved by the present invention are not limited to the above-mentioned technical problems, and other technical problems that are not mentioned can be clearly understood by a person having ordinary knowledge in the relevant field from the description of the present invention.

The present invention provides manufacturing method of high-resolution LIG, including: a) a step of depositing a metal on a wafer to manufacture a metal-deposited wafer; b) a step of spin-coating the metal-deposited wafer with a poly(amic acid) (PAA) solution; c) a step of patterning the spin-coated PAA by irradiating it with ultraviolet (UV) light; d) a step of imidizing the patterned PAA by applying heat thereto to manufacture polyimide (PI); and e) a step of irradiating the PI with a laser to manufacture laser-induced graphene.

In the present invention, the step a) includes: a1) a step of cleaning a wafer; a2) a step of spin-coating the cleaned wafer with a negative photoresist solution; a3) a step of patterning the spin-coated wafer by irradiating it with UV light; a4) a step of depositing a metal on the patterned wafer; and a5) a step of removing a source/drain (S/D) electrode present on the metal-deposited wafer with acetone.

In the present invention, the metal is gold (Au).

In the present invention, the wafer is an SiO₂/Si wafer.

In the present invention, in the step b), a PAA solution is dropped onto the metal-deposited wafer to spin-coat at 400 to 600 rpm for 40 to 60 seconds.

In the present invention, the step c) is a step of patterning by irradiating the spin-coated PAA with UV light having a wavelength of 330 to 400 nm and a light dose of 250 to 350 mJ/cm².

In the present invention, in the step d), the patterned PAA is imidized by heating on a hot plate at 200 to 300° C. for 10 to 300 minutes.

In the present invention, in the step e), the LIG is manufactured by irradiating the PI with a laser at an irradiance of 5.0 to 20.0 kW/cm².

In the present invention, the high-resolution LIG has a resolution of 5 to 15 μm for individual LIG widths.

In the present invention, the metal is gold (Au).

In the present invention, the wafer is an SiO₂/Si wafer.

In the present invention, in the step a1), the wafer is cleaned with acetone, isopropanol, and deionized water.

In the present invention, in the step a3), the spin-coated wafer is patterned by irradiating with UV light having a wavelength of 330 to 400 nm and a light dose of 350 to 450 mJ/cm².

In addition, the present invention provides high-resolution LIG manufactured by the manufacturing method of high-resolution LIG.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings.

FIG. 1 shows a schematic diagram illustrating the laser-induced graphene (LIG) and an LIG-field effect transistor (FET) and an inverter manufactured including the same.

FIG. 2 shows a diagram illustrating the results of analyzing the chemical and structural properties of the LIG.

FIG. 3 shows a diagram illustrating the results of analyzing the structural and electrical properties of an Au/LIG junction.

FIG. 4 shows a diagram illustrating the results of analyzing the transfer properties of LIG used in a channel of the LIG-FET.

FIG. 5 shows a diagram illustrating the results of analyzing the transfer properties of the LIG-FET according to the V_{DS} value.

FIG. 6 shows a diagram illustrating the results of observing the LIG with a scanning electron microscope (SEM) after forming the LIG by irradiating each of photoresist (PR) and polyimide (PI) with laser.

FIG. 7 shows a diagram illustrating the results of analyzing the Raman spectrum after forming the LIG by irradiating each of the PR and PI with laser.

### DETAILED DESCRIPTION

The terms used herein are selected as general terms that are currently widely used as much as possible while considering the functions in the present invention, but they may vary depending on the intention or precedent of those of ordinary skill in the art, the emergence of new technology, or the like. In addition, in certain cases, there are terms arbitrarily selected by the applicant, and in this case, the meaning will be described in the corresponding part of the detailed description of the invention. Therefore, the terms used in the present invention should be defined based on the meaning of the terms and the overall content of the present invention, rather than simply the names of the terms.

Unless otherwise defined, all terms, including technical and scientific terms used herein, have the same meaning as generally understood by one of ordinary skill in the art to which the present invention pertains. Terms, such as those defined in commonly used dictionaries, should be interpreted as having a meaning that is consistent with their meaning in the context of the relevant art and are not interpreted in an idealized or overly formal sense unless clearly so defined in the present invention.

Numerical ranges are inclusive of the values defined therein. Every maximum numerical limitation given throughout the present specification includes every lower numerical limitation, as if such lower numerical limitations were expressly written. Every minimum numerical limitation given throughout the present specification includes every higher numerical limitation, as if such higher numerical limitations were expressly written. Every numerical limitation given throughout the present specification will include every better numerical range within the broader numerical range, as if the narrower numerical limitations were expressly written.

Hereinafter, the terms used herein are explained in detail.

The term “metal” as used herein may refer to a conductive electrode material, and the metal may be a material that is hard and glossy and has high thermal and electrical conductivity to serve as a conductive wiring electrode on a chip. Preferably, the metal may be an alloy of Si, Au, Ag, Al, Cu, Ni, W, Mo, Ti, Pd, and Pt with an Al alloy, a NiCr alloy, a Au—Pt alloy, and an Ag—Cu alloy, a carbon-based material such as graphene or carbon nanotubes, and an oxide such as ITO, Al₂O₃, ZnO, NiO, CuO, or TiO₂, and more preferably, it may be gold (Au).

The term “wafer” as used herein may refer to a thin substrate for fabricating a semiconductor integrated circuit, and preferably it may be a Si wafer, a Ge wafer, a GaAs wafer, a SiC wafer, an InP wafer, a sapphire wafer, a glass wafer, or a SiO₂/Si wafer, and more preferably may be a SiO₂/Si wafer.

Hereinafter, the present invention will be described in detail.

### Manufacturing Method of High-Resolution Laser-Induced Graphene (LIG)

The present invention provides a manufacturing method of high-resolution LIG, including: a) a step of depositing a metal on a wafer to manufacture a metal-deposited wafer; b) a step of spin-coating the metal-deposited wafer with a poly(amic acid) (PAA) solution; c) a step of patterning the spin-coated PAA by irradiating it with ultraviolet (UV) light; d) a step of imidizing the patterned PAA by applying heat thereto to manufacture polyimide (PI); and e) a step of irradiating the PI with a laser to manufacture laser-induced graphene.

The step a) may include: a1) a step of cleaning a wafer; a2) a step of spin-coating the cleaned wafer with a negative photoresist solution; a3) a step of patterning the spin-coated wafer by irradiating it with UV light; a4) a step of depositing a metal on the patterned wafer; and a5) a step of removing a source/drain (S/D) electrode present on the metal-deposited wafer with acetone.

In the step b), a PAA solution may be dropped onto the metal-deposited wafer to spin-coat at 400 to 600 rpm for 40 to 60 seconds, and preferably, a PAA solution may be dropped onto the metal-deposited SiO₂/Si wafer to spin-coat at 480 to 520 rpm for 45 to 55 seconds, and more preferably, a PAA solution may be dropped onto the metal-deposited SiO₂/Si wafer to spin-coat at 495 to 505 rpm for 48 to 52 seconds.

The step c) may be a step of patterning by irradiating the spin-coated PAA with UV light having a wavelength of 330 to 400 nm and a light dose of 250 to 350 mJ/cm², preferably, it may be a step of patterning by irradiating the spin-coated PAA with UV light having a wavelength of 360 to 370 nm and a light dose of 280 to 320 mJ/cm², and more preferably, it may be a step of patterning by irradiating the spin-coated PAA with UV light having a wavelength of 364 to 366 nm and a light dose of 295 to 305 mJ/cm².

In the step d), the patterned PAA may be imidized by heating on a hot plate at 200 to 300° C. for 10 to 300 minutes to manufacture PI, preferably, the patterned PAA may be imidized by heating on a hot plate at 240 to 260° C. for 20 to 40 minutes to manufacture PI, and more preferably, the patterned PAA may be imidized by heating on a hot plate at 245 to 255° C. for 28 to 32 minutes to manufacture PI.

The PI manufactured in the step d) may have a width of 1 to 5,000 μm, and preferably a width of 5 to 100 μm. More specifically, when the width of the PI is less than 5 μm, there is a concern that the boundary of the LIG pattern may become unclear, making it difficult to specify the resolution, and when the width of the PI exceeds 100 μm, there is a concern that no distinct advantage may be exhibited compared to un-patterned PI.

The laser used in the step e) may be a CO₂ laser, a gas laser such as a He—Ne laser or an Ar laser, a solid-state laser such as a Nd:YAG laser or a ruby laser, a dye laser, a diode laser, a fiber laser, an excimer laser, or a free electron laser, and preferably a CO₂ laser.

In the step e), the LIG may be manufactured by irradiating the PI with a CO₂ laser at an irradiance of 5.0 to 20.0 kW/cm², preferably, the LIG may be manufactured by irradiating the PI with a CO₂ laser at an irradiance of 12.0 to 16.0 kW/cm², and more preferably, the LIG may be manufactured by irradiating the PI with a CO₂ laser at an irradiance of 13.5 to 14.5 kW/cm².

More specifically, in the step e), when the CO₂ laser irradiation is less than 12.0 kW/cm², there is a concern that the PI may not be completely graphitized, resulting in the formation of LIG with many defects and low crystallinity, and when it exceeds 18.0 kW/cm², there is a concern that LIG may be oxidized or damaged due to excessive laser energy.

In the step a1), the wafer may be cleaned with acetone, isopropanol, and deionized water.

In the step a2), a negative photoresist solution may be sprayed to spin coat on the cleaned wafer.

In the step a3), the spin-coated wafer may be patterned by irradiating with UV light having a wavelength of 330 to 400 nm and a light dose of 350 to 450 mJ/cm², and preferably, the spin-coated wafer may be patterned by irradiating with UV light having a wavelength of 360 to 370 nm and a light dose of 380 to 420 mJ/cm², and more preferably, the spin-coated wafer may be patterned by irradiating with UV light having a wavelength of 364 to 366 nm and a light dose of 395 to 405 mJ/cm².

In addition, the present invention may provide high-resolution LIG manufactured according to the manufacturing method of LIG.

The average Dirac voltage (V_{Dirac}) of the LIG may be −20 to 150 V, preferably 0.8 to 1.2 V. The average μ_{Electron} and μ_{Hole} may be 13.0 to 14.5 cm²/V·s and 16.7 to 20.2 cm₂/V·s, respectively.

### Field Effect Transistor (LIG-FET) Including LIG

The present invention provides a field effect transistor (LIG-FET) including high-resolution LIG manufactured according to the manufacturing method of LIG.

The LIG-FET may further include an ionic liquid, and the ionic liquid may be deposited on the LIG. Non-limiting examples of the ionic liquid may include an aliphatic ionic liquid, an imidazolium-based ionic liquid, a polymer electrolyte, gel electrolyte, solide-state electrolyte, aqueous based electrolytes, organic electrolytes, or a mixture thereof, and preferably, an imidazolium-based ionic liquid.

Hereinafter, examples of the present invention will be described in detail, but it is obvious that the present invention is not limited to the examples described below.

### Example 1. Manufacture of High-Resolution LIG

### 1-1. Manufacture of Metal-Deposited SiO₂/Si Wafer

A SiO₂/Si wafer with a dielectric layer thickness of 100 nm was prepared and cleaned using acetone, isopropanol, and deionized water. A negative photoresist (PR) solution (AZ Electronic Materials, AZ GXR-601) was sprayed on the cleaned wafer and spin-coated. Thereafter, the specific position of a source-drain (S/D) electrode was defined and patterned using UV lithography (365 nm, 400 mJ/cm²). A contact metal (Au, 50 nm) was thermally deposited on the unnecessary residual areas of the patterned wafer, and the S/D electrode was removed with acetone.

### 1-2. Fabrication of High-Resolution Laser-Induced Graphene on a Metal-Deposited Wafer

A positive type photo-sensitive PAA (PNS technology, PIP-100) was dropped on the metal-deposited SiO₂/Si wafer manufactured in Example 1-1, and then spin-coated at 500 rpm for 50 seconds. The spin-coated PAA solution was pre-baked at 110° C. for one minute to fix it to the wafer. Next, the spin-coated PAA was patterned using UV-lithography (365 nm, 300 mJ/cm²), and the UV-treated area was decomposed and easily dissolved in a developer (tetramethylammonium hydroxide, TMAH 2.38%). The patterned PAA was thermally imidized on a hot plate at 250° C. for 30 minutes to manufacture PI.

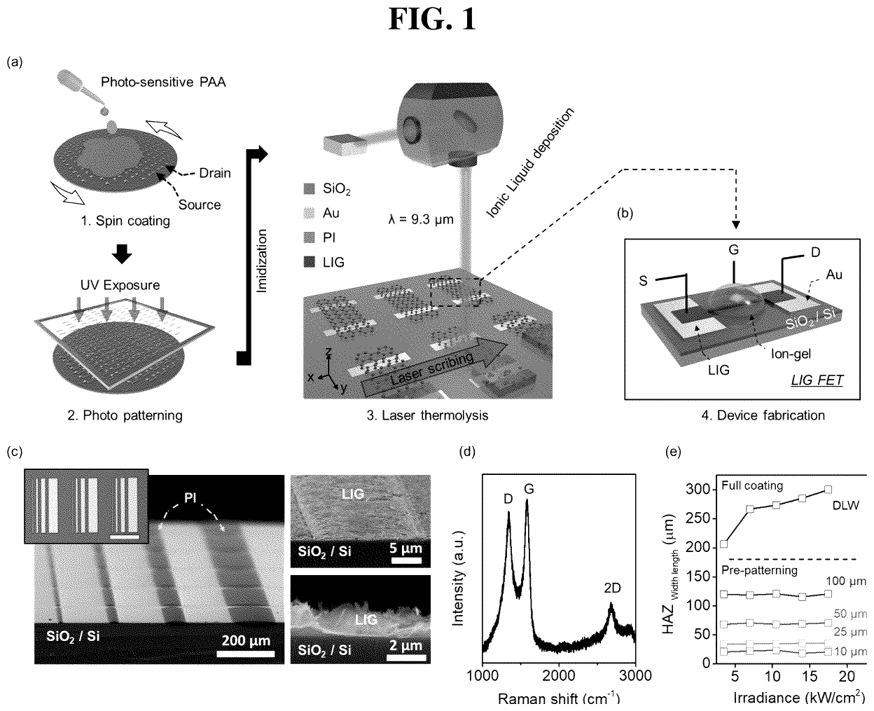

The PI was converted into LIG by irradiating a CO₂ laser with a continuous wavelength CO₂ laser (9.3 μm, 30 W) equipped on the XLS 10 MWH (Universal Laser System). In other words, the PI was thermally graphitized by laser-induced photothermal energy by irradiating the PI with the CO₂ laser with an irradiance of 14.0 kW/cm². The process of Example 1-2 is schematically illustrated in FIG. 1, (a).

### Example 2. Fabrication of LIG-Based FET Device

An imidazolium-based ionic liquid was deposited on the LIG manufactured in Example 1 to activate an LIG-based FET. The LIG positioned between two metal electrodes served as a channel, and each Au metal electrode formed an S/D electrode pair of the LIG-FET. The electronic device of Example 2 is schematically illustrated in FIG. 1, (b).

### Experimental Example 1. Analysis of Structural Properties of Patterned PI and LIG

In order to analyze the structural properties of the patterned PI and LIG manufactured in Example 1, they were observed using an optical microscope and a scanning electron microscope (SEM, APERO, FEI). The results of Experimental Example 1 are illustrated in FIG. 1, (c).

Referring to FIG. 1, (c), the patterned PI was defined as having a length of 1 mm and a width of 10, 25, 50, and 100 μm. In addition, as a result of observing the overall shape of the LIG, a slight increase of the surface roughness was observed, but no significant deformation of the shape occurred.

### Experimental Example 2. Raman Spectrum Analysis of LIG

The Raman spectrum of LIG manufactured in Example 1 was analyzed using Raman spectroscopy (Lab Gramn GR, Horiba, 514 nm) in the range of 1000 to 3000 cm⁻¹. The results of Experimental Example 2 are graphically represented in FIG. 1, (d).

Referring to FIG. 1, (d), in the range of 1000 to 3000 cm⁻¹, the LIG exhibits three distinct sp2 carbon peaks: the D peak at ˜1350 cm⁻¹; the G peak at ˜1580 cm⁻¹; and the 2D peak at ˜2700 cm⁻¹. More specifically, the D band indicates the presence of local disorder and defects of carbon corresponding to phonon scattering, the G band indicates the in-plane tangential stretching of C—C bonds in sp2 hybridized carbon, and the 2D band indicates two phonons having opposite wave vectors in a defect-free structure. In particular, the appearance of a 2D band is commonly used to distinguish electronically isolated graphite from amorphous carbon. In other words, a distinct 2D peak found in the Raman spectrum of the LIG may be considered as implying the formation of a crystallized graphite structure.

### Experimental Example 3. Analysis of Change in Resolution According to Laser Irradiance on LIG

The resolution change of LIG according to the laser irradiance was analyzed, and the resolution was analyzed in terms of the laser-affected heat-affected zone (HAZ). The laser was irradiated on two types of substrates at a constant laser scribing speed (5 mm/s). The two types of substrates corresponded to (\textcircled{1}) a substrate coated with PI over the entire substrate and (\textcircled{2}) substrates in which the patterned PI was partially present within the substrates and the pattern widths were 10, 25, 50, and 100 μm (Example 1). The results of Experimental Example 3 are shown graphically in FIG. 1, (e).

Referring to FIG. 1, (e), the substrate (\textcircled{1}) in which PI was coated on the entire substrate showed a large change in the HAZ as the laser irradiance increased from 3.5 to 17.5 kW/cm². More specifically, when the laser irradiance was 3.5 kW/cm², a HAZ of about 200 μm was generated, and when the laser irradiance was 17.5 kW/cm², a HAZ of about 300 μm was generated. On the other hand, in the case of the substrates (\textcircled{2}) in which the patterned PI was partially present within the substrates and the pattern widths were 10, 25, 50, and 100 μm, the HAZ change according to the laser irradiance was not significant, and a HAZ of 1 μm or less was generated at all the pattern widths. This is because the heat generation that occurs during laser irradiation spreads beyond the laser spot size in the substrate coated with PI over the entire surface, which inevitably results in a large HAZ. However, in the case of the patterned PI, heat generation occurs only within the patterned PI, so the HAZ is drastically reduced, making it possible to produce LIG with both superior quality and high resolution.

### Experimental Example 4. Analysis of Chemical and Structural Properties of LIG

### 4-1. Analysis of Raman Spectra of PI and LIG According to Laser Irradiance

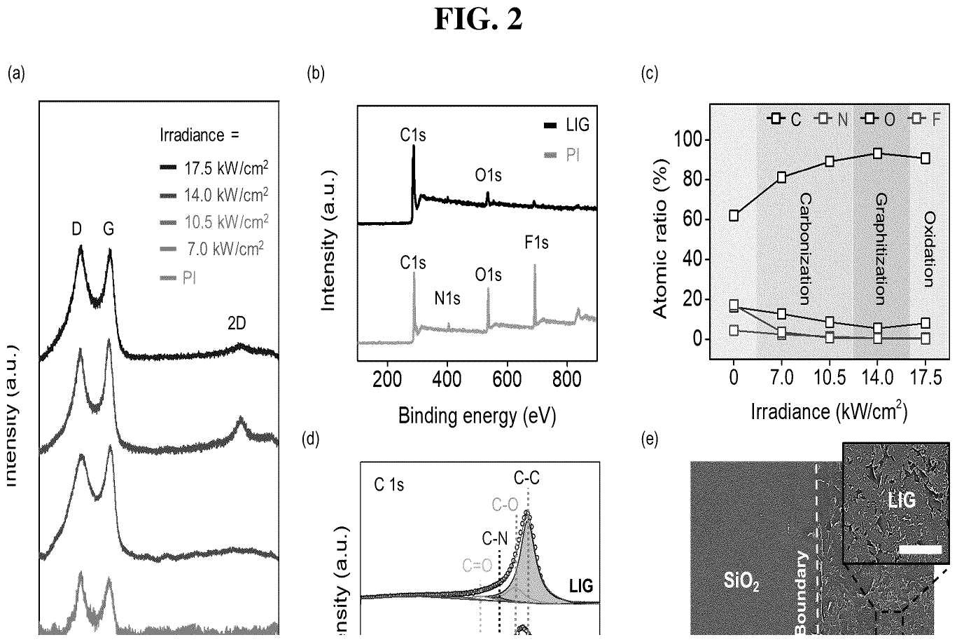

The Raman spectra of the LIG manufactured in Example 1 was analyzed in the same manner as in Experimental Example 2. However, in Experimental Example 4-1, the Raman spectra were analyzed while increasing the laser irradiance to 7.0 to 17.5 kW/cm². The results of Experimental Example 4-1 are shown graphically in FIG. 2, (a).

Referring to FIG. 2, (a), no distinct peak was observed in the PI in the range of 1000 to 3000 cm⁻¹. On the other hand, D and G peaks were observed in the LIG irradiated with a laser, and the peak intensities of both peaks increased as the laser irradiance increased. When the laser irradiance was 14.0 kW/cm², the full width at half maximum (FWHM) of the D and G peaks narrowed and a 2D peak appeared, indicating the presence of graphitic sp2 carbon. In particular, the 2D peak indicates that the optical energy injection allows a temperature that is sufficient to induce graphitization. However, when the laser irradiance was 17.5 kW/cm², the FWHM of the D peak broadened and the intensity increased, but the peak intensity of the 2D peak weakened. This is because the LIG was partially oxidized due to the overheating in the surrounding environment, which reduced the structural crystallinity.

### 4-2. Chemical Composition Analysis of PI and LIG

The XPS spectrum of the LIG manufactured in the above Example 1 was measured by X-ray photoelectron spectroscopy (Thermo Fisher Scientific, K-alpha). The results of Experimental Example 4-2 are shown in FIG. 2, (b).

Referring to FIG. 2, (b), the PI was composed of carbon, oxygen, nitrogen, and fluorine atoms, but peaks corresponding to only carbon and oxygen atoms were observed in the LIG.

Referring to FIG. 2, (c), the change in the atomic proportions in the LIG according to the laser irradiance may be known. As the laser irradiance increased from 7.0 to 14.0 kW/cm², the carbon proportion increased, but the nitrogen, oxygen, and fluorine element proportions slightly decreased. However, as the laser irradiance increased to the oxidation point (17.5 kW/cm²), the carbon proportion slightly decreased and the oxygen proportion slightly increased. Therefore, when the laser irradiance was 14.0 kW/cm², the graphitization of PI occurred most effectively, and when the laser irradiance reached the oxidation point (17.5 kW/cm²), oxidation occurred, so the optimal laser irradiance may be considered to be 14.0 kW/cm².

Referring to FIG. 2, (d), the C is core level XPS spectra of the PI and LIG may be known. In the PI, various heteroatoms bonded with carbon were present, but in the LIG, the proportions of the heteroatoms decreased rapidly due to laser thermal decomposition. In other words, C—O, C—N, C═O, O═C—O, and C═F₂ bonds may be easily broken to form stable aromatic C—C compounds.

### 4-3. SEM Microscopic Observation Between SiO₂ and LIG

The boundary between SiO₂ and the LIG was observed using a SEM microscope, and the results are shown in FIG. 2, (e). Referring to FIG. 2, (e), it was confirmed that a distinct boundary was exhibited between SiO₂ and the LIG. In other words, it was confirmed that the LIG can be selectively synthesized.

### Experimental Example 5. Analysis of Structural and Electrical Properties of Au/LIG Junction

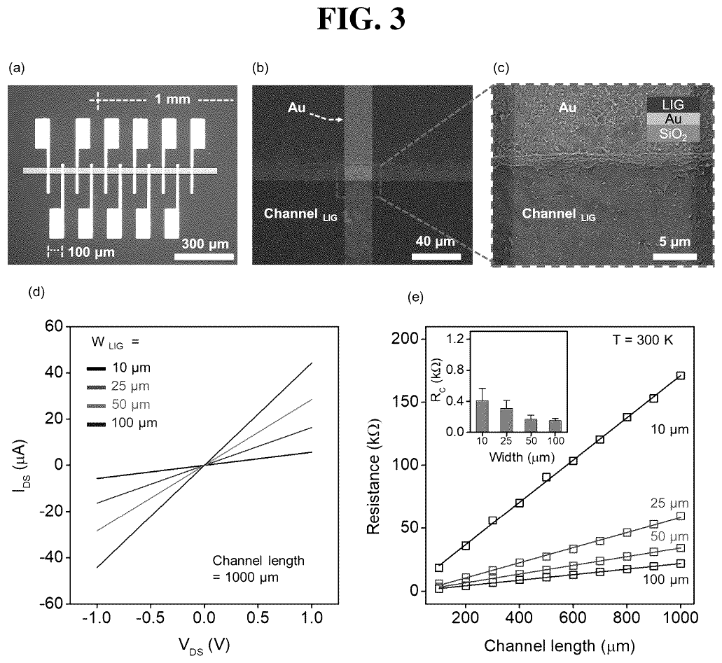

In order to investigate whether the LIG manufactured in Example 1, which served as a channel layer, is feasible as an on-chip device, the physical and electrical bonding properties with metal wiring electrodes were observed. Referring to FIG. 3, (a), which shows the manufactured Au/LIG vertical junction, a 1 mm-long PI pattern was manufactured on 11 Au electrodes, each of which had a gap of 100 μm between the electrodes. At this time, as described in Experimental Example 4-3, it was confirmed that the pattern, which is the metal wiring electrode, was not damaged when the LIG was selectively synthesized.

### 5-1. SEM Observation of Au/LIG Junction

The Au/LIG junction was observed through a SEM (APERO, FEI), and the results are shown in FIG. 3, (b) and (c). Referring to FIG. 3, (b) and (c), the dark region represents LIG, and the bright region represents Au. In other words, it was confirmed that LIG was selectively synthesized by selectively irradiating the PI region without damaging the Au electrode through laser irradiation.

### 5-2. I-V Curve Analysis According to LIG Width

The I-V curves of the LIGs manufactured with a length of 1 mm and widths of 10, 25, 50, and 100 μm were analyzed, and the results are shown graphically in FIG. 3, (d). Referring to FIG. 3, (d), all the LIGs showed linear plots despite the decrease in I_{DS} as the charge transfer path narrowed. This proved the stable charge transfer characteristics of the LIG channel.

### 5-3. Analysis of Transmission Line Method (TLM) Resistance Values According to LIG Width

The contact resistance (RC) between Au and LIG was measured using the TLM. More specifically, the I-V slope was analyzed while applying a constant power to the Au electrode pair separated by 100 μm, and the resistance value was measured under the conditions of 100 to 1000 μm channel length, and the results are shown graphically in FIG. 3, (e).

Referring to FIG. 3, (e), the resistance value has a constant slope according to the LIG channel length. Therefore, the contact resistance between Au and LIG may be inferred at the 0 μm channel length point through a linear plot. In addition, referring to the bar graph in FIG. 3, (e), it was confirmed that there was a reasonable RC value of 0.5 kΩ or less at all LIG widths. In other words, the results suggest that the LIG according to the present invention not only has a high-resolution effect by improving the resolution, but also can be utilized as an LIG-based on-chip device.

### Experimental Example 6. Analysis of Transfer Properties of LIG Used in Channels of LIG-FET

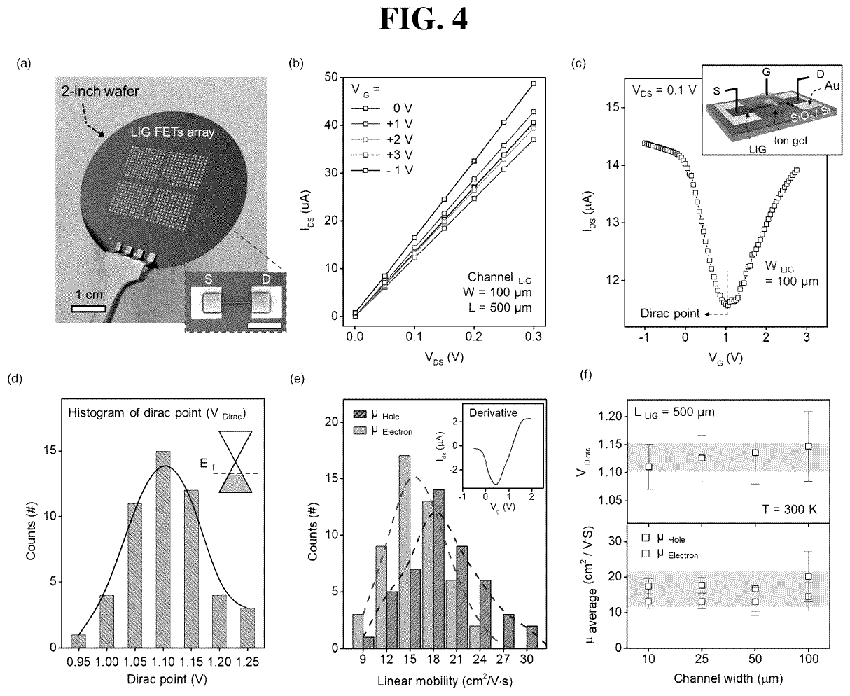

A micro-patterned LIG-FET array was fabricated on a 2-inch SiO₂/Si wafer using the same method as in Example 1. The dimensions of the fabricated LIG channels were to be 500 μm in length and 100 μm in width. A schematic diagram of the fabricated LIG-FET array is shown in FIG. 4, (a). The transfer properties of the fabricated LIG-FET were measured using a parameter analyzer (Keithley 4200-SCS) while the LIG-FET was stored in a vacuum (˜10-3 Torr) shielded probe station (MSTECH, M5VC).

6-1. Comparison of I_{DS} and V_{DS} Characteristics of LIG-FET According to V_{G} Value

Referring to FIG. 4, (b), the output curve (I_{DS} vs V_{DS}) according to V_{G} value is shown, and the five curves show the I_{DS} change between −1 and +3 V. In other words, the I_{DS} was confirmed to be maximum at −1 V and minimum at +1 V, showing the typical properties of a p-type graphene channel.

6-2. Analysis of Transfer Properties of LIG-FET Under the condition of V_{D}S of 0.1 V

Referring to FIG. 4, (c), the graph shows an asymmetric V-shaped (bipolar) transport, where the charge is neutralized at the Dirac point. In the undoped graphene transistor, the Dirac point is usually observed at 0 V, but in the fabricated LIG-FET, the Dirac point shifted to +1 V due to the p-doping effect induced from the residual heteroatoms.

6-3. Analysis of V_{Dirac}, μ_{Electron}, and μ_{Hole} of LIG-FET

To argue the uniformity of LIG-FET array, 50 randomly selected devices were electrically characterized, and the statistical distribution of V_{Dirac} and the carrier mobility (P) are shown in FIG. 4, (d) and (e). Referring to FIG. 4, (d), the average of V_{Dirac} was found to be 1.10 to 1.15 V. Referring to FIG. 4, (e), the average of μ_{Electron} and μ_{Hole} were calculated to be 13.0 to 14.5 cm²/V·s and 16.7 to 20.2 cm²/V·s, respectively.

### Experimental Example 7. Analysis of LIG-FET Transfer Properties According to V_{D}S Value

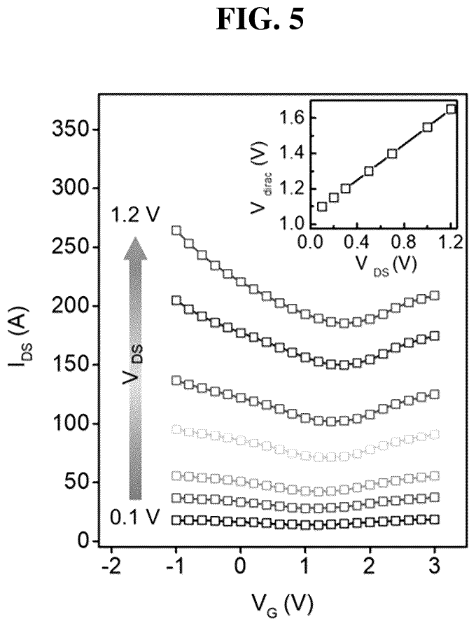

The change in V_{Dirac} value was investigated by setting the V_{D}S value to various values from 0.1 to 1.2 V, and the results are shown graphically in FIG. 5. Referring to FIG. 5, as the V_{D}S value increased from 0.1 to 1.2 V, V_{Dirac} shifted from 1.1 V to 1.65 V due to the drain overlap effect.

### Experimental Example 8. Comparison of LIG Formation Effects of PR and PI

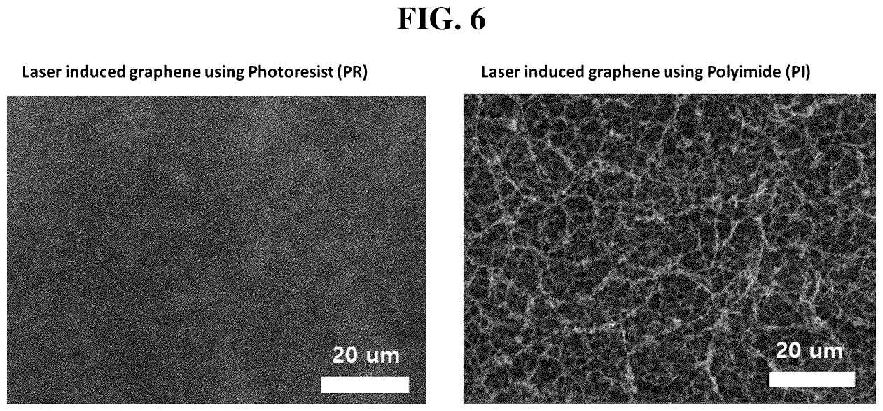

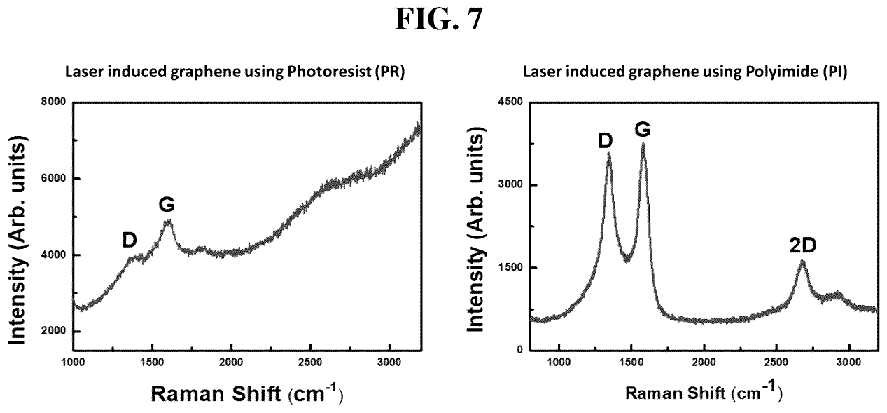

PR and PI were irradiated with a CO₂ laser to form LIG. The method of forming LIG in the PR and PI was performed in the same manner as in Example 1. The results of observing the PR and PI using a SEM (APERO, FEI) after the LIG formation are shown in FIG. 6, and the results of analyzing the Raman spectrum are shown in FIG. 7.

Referring to FIG. 6, LIG was not formed well even when the PR was irradiated with a laser and photothermally decomposed, but LIG was formed well on the PI. Referring to FIG. 7, no 2D band was observed when the PR was irradiated with a laser, but a 2D band was observed when the PI was irradiated with a laser. The distinct 2D peak in the Raman spectrum of LIG indicates that a crystallized graphite structure has been formed, so it was observed that LIG was formed better on the PI than on the PR.

The present invention can provide a manufacturing method of LIG having a porous structure on a semiconductor substrate (SiO₂/Si wafer) rather than a polymer substrate, thereby achieving compatibility with the post-process of the semiconductor device manufacturing process and providing a manufacturing method of LIG having excellent resolution.

In addition, the present invention can provide LIG manufactured by a method according to the manufacturing method of LIG.

The effects of the present invention are not limited to the above-mentioned effects, and other effects that are not mentioned may be clearly understood by a person having ordinary knowledge in the relevant field from the description of the claims.

From the above description, those skilled in the art will be able to understand that the present invention may be implemented in other specific forms without changing the technical idea or essential features of the present invention. In this regard, it should be understood that the above-described examples are exemplary in all respects and not limiting.

1. A manufacturing method of high-resolution laser-induced graphene (LIG), comprising:
a) a step of depositing a metal on a wafer to manufacture a metal-deposited wafer;
b) a step of spin-coating the metal-deposited wafer with a poly(amic acid) (PAA) solution;
c) a step of patterning the spin-coated PAA by irradiating it with ultraviolet (UV) light;
d) a step of imidizing the patterned PAA by applying heat thereto to manufacture polyimide (PI); and
e) a step of irradiating the PI with a laser to manufacture laser-induced graphene.

2. The manufacturing method of high-resolution LIG according to claim 1, wherein the step a) includes:
a1) a step of cleaning a wafer;
a2) a step of spin-coating the cleaned wafer with a negative photoresist solution;
a3) a step of patterning the spin-coated wafer by irradiating it with UV light;
a4) a step of depositing a metal on the patterned wafer; and
a5) a step of removing a source/drain (S/D) electrode present on the metal-deposited wafer with acetone.

3. The manufacturing method of high-resolution LIG according to claim 1, wherein the metal is gold (Au).

4. The manufacturing method of high-resolution LIG according to claim 1, wherein the wafer is an SiO₂/Si wafer.

5. The manufacturing method of high-resolution LIG according to claim 1, wherein, in the step b), a PAA solution is dropped onto the metal-deposited wafer to spin-coat at 400 to 600 rpm for 40 to 60 seconds.

6. The manufacturing method of high-resolution LIG according to claim 1, wherein the step c) is a step of patterning by irradiating the spin-coated PAA with UV light having a wavelength of 330 to 400 nm and a light dose of 250 to 350 mJ/cm².

7. The manufacturing method of high-resolution LIG according to claim 1, wherein, in the step d), the patterned PAA is imidized by heating on a hot plate at 200 to 300° C. for 20 to 40 minutes.

8. The manufacturing method of high-resolution LIG according to claim 1, wherein, in the Step e), the LIG is manufactured by irradiating the PI with a CO₂ laser at an irradiance of 12.0 to 16.0 kW/cm².

9. The manufacturing method of high-resolution LIG according to claim 1, wherein the high-resolution laser-induced graphene has a resolution of 5 to 15 μm for individual laser-induced graphene widths.

10. The manufacturing method of high-resolution LIG according to claim 2, wherein the metal is gold (Au).

11. The manufacturing method of high-resolution LIG according to claim 2, wherein the wafer is an SiO₂/Si wafer.

12. The manufacturing method of high-resolution LIG according to claim 2, wherein, in the step a1), the wafer is cleaned with acetone, isopropanol, and deionized water.

13. The manufacturing method of high-resolution LIG according to claim 2, wherein, in the step a3), the spin-coated wafer is patterned by irradiating with UV light having a wavelength of 330 to 400 nm and a light dose of 350 to 450 mJ/cm².
